(19) United States
(12) Patent Application Publication
(10) Pub. No.: US 2025/0164317 A1
(43) Pub. Date: May 22, 2025

(54) TEMPERATURE MEASURING SYSTEM FOR POWER SEMICONDUCTORS ARRANGED ON A BASE PLATE OF AN INVERTER

(71) Applicant: ZF Friedrichshafen AG, Friedrichshafen (DE)

(72) Inventors: Johannes Maier, Bamberg (DE); Thomas Schober, Hahnbach (DE); Dominik Fries, Schwarzenfeld (DE); Armin Schmidbauer, Schnabelwaid (DE); Claudia Kleinschrodt, Bayreuth (DE)

(73) Assignee: ZF Friedrichshafen AG, Friedrichshafen (DE)

(21) Appl. No.: 18/948,821

(22) Filed: Nov. 15, 2024

(30) Foreign Application Priority Data
Nov. 16, 2023 (DE) 10 2023 211 384.8

(51) Int. Cl. G01K 1/14; B60L 15/00; G01K 7/22; H02M 7/00; H05K 7/20

(52) U.S. Cl. CPC G01K 1/14; B60L 15/007; G01K 7/22; H02M 7/003; H05K 7/2089; B60L 2240/425

(57) ABSTRACT

A temperature measuring system for a power semiconductor on top of a base plate functioning as a cooling plate for an inverter, wherein coolant is conducted along the bottom of the base plate and underneath the power semiconductors, wherein the temperature measuring system includes a substrate made of an electrically non-conductive material that can be attached to the base plate, at least one temperature sensor embedded in or attached to the substrate, and electrical contact elements attached to or partially embedded in the substrate, and which protrude above the substrate, wherein the substrate is placed on the base plate such that each temperature sensor is placed above where the coolant is conducted and mechanically attached to the base plate such that it is in thermally conductive contact therewith.

### CROSS-REFERENCE TO RELATED APPLICATION

This application claims priority to German Patent Application No. 10 2023 211 384.8, filed on Nov. 16, 2023, the entirety of which is hereby fully incorporated by reference herein.

### TECHNICAL FIELD

The present disclosure relates to the field of electric mobility, in particular the cooling of power semiconductors in a power electronics module for an electric drive.

### BACKGROUND

Electronic modules, i.e. power electronics modules, have been used to an increasing extent in motor vehicles over the previous decades. This is because of the necessity of conserving fuel and improving vehicle performance, as well as because of the advances in semiconductor technology. The main components in such a power electronics module are an electronic control unit (ECU), which is connected to or part of the vehicle control units and receives control signals and/or information based on driving behavior or signals from other control units, and a DC/AC inverter, with which electric machines such as motors or generators are provided with a multiphase alternating current (AC). This involves converting direct current generated by a DC power source such as a battery into a multiphase alternating current. The inverters contain numerous electronic components for this that form bridge circuits (half bridges), e.g. semiconductor switches, also referred to as power semiconductors.

Power semiconductors are temperature sensitive and must therefore be cooled with a cooling system. The base plate, the upper surface of which is populated with power semiconductors, serves as a cooling plate. There is a canal structure on the lower surface of the cooling plate through which a coolant flows. Because the base plate is made of a thermally conductive material such as copper or aluminum, the temperature is conveyed from the lower surface of the base plate to the upper surface, and thus to the power semiconductors, to cool them.

The challenges involved in measuring temperatures in inverters relate to the insulation between the high and low voltages, depending on where the temperature sensor is located. Signal transfer, i.e. the time between taking a measurement and processing the measurement, as well as the response time of the temperature sensors and the available installation space, in particular the space on the printed circuit board for signal processing, must be taken into account. Thermal contact during vibration and thermal expansion must also be considered when measuring temperatures.

There are numerous ways of monitoring the temperature of power semiconductors. Temperature monitoring can be integrated directly in the power semiconductor module as a temperature sensor or sensor diodes. The temperature can also be measured directly on the power semiconductors, i.e. on the housing (coating) thereof. The measurement can take place with or without contact to the housing.

Because there is still room for improvement in measuring temperatures of power semiconductors in an inverter, an object of the present disclosure is to create a better temperature measuring system for measuring the temperatures of power semiconductors in an inverter.

### SUMMARY

This problem is solved by the features disclosed herein. Advantageous embodiments are also disclosed herein.

A temperature measuring system for power semiconductors on the upper surface of a base plate serving as a cooling plate for an inverter is proposed, in which coolant is conducted along the lower surface of the base plate, at least underneath the power semiconductors, which is supplied through at least one first coolant inlet on the edge of the base plate and drained through at least one coolant outlet on the edge of the base plate, wherein the temperature measuring system contains a substrate made of an electrically nonconductive material that can be attached to the base plate, at least one temperature sensor embedded in or attached to the substrate, and contact elements attached to or partially embedded in the substrate, which, extending upward from the substrate, are in electrical contact with the temperature sensor, wherein the substrate is mounted on a part of the base plate such that each temperature sensor is above an area where coolant is conducted, and mechanically attached to the base plate such that it is in thermally conductive contact with the base plate.

In one embodiment, a temperature sensor is near at least one coolant outlet and/or at least one coolant inlet.

In one embodiment, a lead frame is embedded in the substrate, which is in electric contact with the at least one temperature sensor.

In one embodiment, a plate is embedded in the substrate, which is in electric contact with the at least one temperature sensor, and faces the base plate.

In one embodiment, the at least one temperature sensor is an SMD component or a through-hole component.

In one embodiment, the substrate has a pocket if the at least one temperature sensor is a through-hole component, into which at least part of the temperature sensor is inserted.

In one embodiment, the contact elements are formed by spring contacts, through-hole pins, press-fit pins, flex foil, ribbon cable or assembly aids for flexible electric leads that protrude from the upper surface of the base plate.

In one embodiment, the parts of the base plate where temperature sensors are placed are the edges, or areas between two phases of the inverter.

In one embodiment, the substrate is attached to the base plate with at least one threaded fastener.

In one embodiment, at least one additional functional component is embedded in the substrate or placed thereon, which comprises at least one RAD resistor.

An inverter is also obtained with the present disclosure that has a base plate functioning as a cooling plate, which is populated with power semiconductors on the upper surface and has a region for conducting coolant on the lower surface, at least below the power semiconductors, in which the coolant is supplied through at least one inlet on the edge of the base plate, and drained through at least one outlet on the edge of the base plate, a printed circuit board above the power semiconductors designed to at least conduct signals, and at least one temperature measuring system like that described above, the substrate of which is attached to the base plate such that the at least one temperature sensor is in thermal contact with the base plate and is connected to the printed circuit board for signal transfer.

An electric drive for a vehicle is also obtained, in particular an electric axle drive, which has at least one electric machine, a transmission, and an electronics module for controlling the electric drive that contains the inverter.

Other features and advantages can be derived from the following description of exemplary embodiments in reference to the drawings showing details of the present disclosure, and from the claims. The individual features can be implemented in and of themselves or in various arbitrary combinations to obtain variations of the present disclosure.

Preferred embodiments of the present disclosure shall be explained in greater detail below in reference to the drawings.

### BRIEF DESCRIPTION OF THE DRAWINGS

FIG. 1 shows a base plate with a temperature measuring system according to one embodiment of the present disclosure.

FIG. 2 shows a substrate according to one embodiment of the present disclosure.

FIG. 3 shows components that are to be embedded in the substrate shown in FIG. 2.

FIG. 4 shows a substrate according to another embodiment of the present disclosure.

FIG. 5 shows components that are to be embedded in the substrate shown in FIG. 4.

FIGS. 6 to 8 show other embodiments of the a substrate according to the present disclosure.

FIG. 9 shows the substrate from FIG. 8 on a base plate, the temperature sensors of which are in contact with a printed circuit board.

### DETAILED DESCRIPTION

Identical elements and functions have the same reference symbols in the following descriptions of the drawings.

As is sufficiently known from the prior art, power semiconductors 2 on a base plate 1 for an inverter used in the automotive industry are cooled through heat exchange with the base plate 1, which also serves as a cooling plate, and from there with the coolant conducted along the lower surface thereof. The lower surface of the base plate 1 can also contain structures (e.g. pins or fins) that further improve heat exchange with the coolant. Cooling channels are formed (potentially with a complementary structure) on the lower surface of the base plate 1 underneath the power semiconductors 2 populating the upper surface thereof. The coolant connection, i.e. for supplying and draining coolant, is formed by lines from outside the base plate 1, entering through the edges thereof.

As specified above, the power semiconductors 2 are temperature sensitive, for which reason it is important to monitor their temperature and take measures if the temperature exceeds a threshold value. Instead of measuring the temperature directly on the power semiconductors 2, it may be sufficient to simply measure the temperature of the coolant at one or more points. A substrate 4 attached to the based plate 1 is proposed for monitoring these, on which the temperature sensor 40 that is thermally connected to the base plate 1 is placed (after assembly). An NTC element (thermistor) can be used as the temperature sensor 40. This can be obtained with numerous embodiments, which shall be explained below in reference to the drawings.

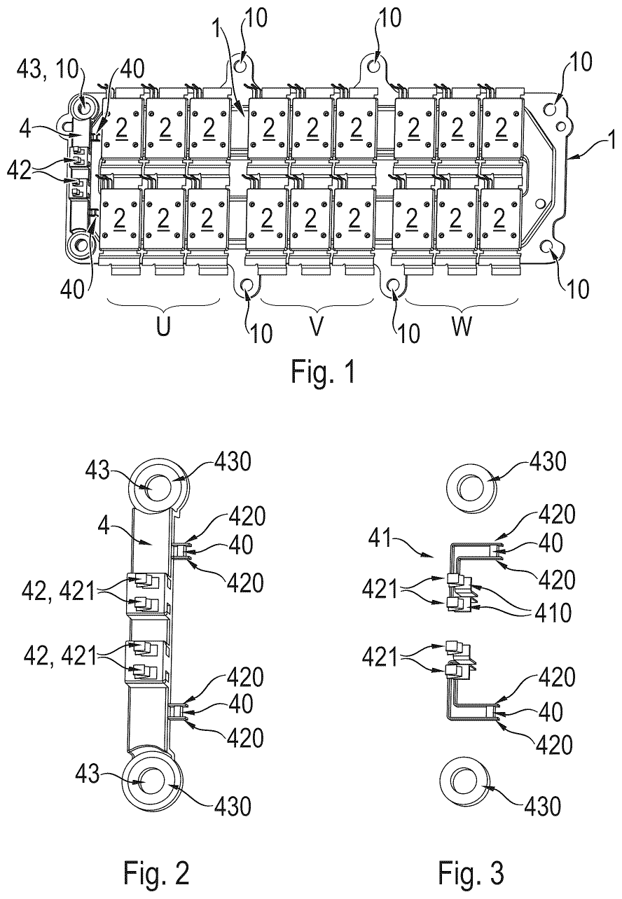

There is a substrate 4 in all of the embodiments, which is made of an electrically nonconductive material such as plastic, e.g. thermoplastic or a thermosetting polymer, attached to the base plate 1. The attachment is advantageously obtained with a threaded fastener at at least one point 10 on the base plate 1, as shown in FIG. 1. The attachment points on the substrate 4 are formed by holes 43 (with or without bushings 430), that are aligned with the respective threaded points 10, such that a threaded fastener can be screwed therein.

The substrate 4 also has at least one temperature sensor 40. This is embedded in or attached to the substrate 4 such that it is thermally connected to the base plate 1. It is preferably placed thereon, potentially with a thermally conductive gap filler forming an intermediate layer, in particular to attach the temperature sensor 40 to the base plate 1 (in a thermally conductive manner), and to reinforce it.

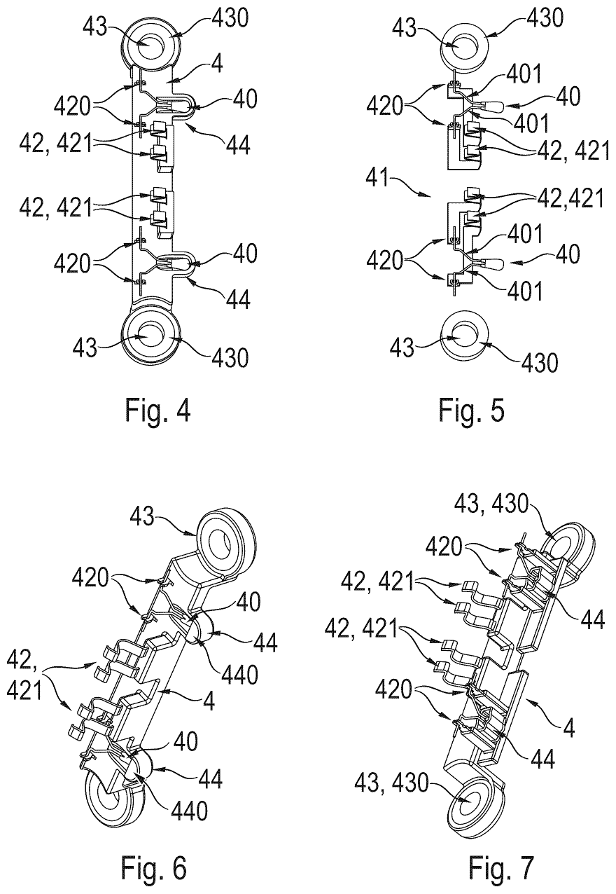

The temperature sensor 40 can be an SMD component (i.e. without protruding contact legs), as shown in FIGS. 1, 2, 3, 8 and 9, or a through-hole component, as shown in FIGS. 4 to 7.

Furthermore, the parts of the temperature sensors 40 for sending the measurement values (signal transmission) are connected to contact elements 42 that come in contact with corresponding contact points on the printed circuit board 3 above the power semiconductors 2. These contact elements 42 are formed by a lead frame 41 in the embodiments shown in FIGS. 1 to 7 (showing the substrate 4 from above), which is embedded in the substrate 4, thus encased in plastic. One end 420 of each contact element 42 is connected to a part of the temperature sensor 40 for signal transfer, and the other end 421 forms a contact for the printed circuit board. These ends can form spring contacts, through-hole pins, press-fit pins, ribbon cables, flex foil, or lands for attaching an electric line 5 (wire). To better attach the lead frame 41 to the plastic, it can have tabs 410.

If the temperature sensor 40 is an SMD component, as shown in FIGS. 1 to 3, the ends 420 of the lead frame 41 are attached directly to the contacts for signal transmission, thus forming both electrical contacts as well as structural reinforcements.

If the temperature sensor 40 is a through-hole component, with signal contacts 401 (contact legs) protruding from the sensor, as sown in FIGS. 4 to 7, the ends 420 of the lead frame 41 are also connected to contacts (contact legs) for signal transmission. In this embodiment, the substrate 4 also has a pocket 44 surrounding the actual sensor. Different orientations of the temperature sensor 40 are shown in FIGS. 4, 6 and 7. These depend on the available installation space and the type of temperature sensor. In the embodiment shown in FIGS. 4 and 6, the temperature sensor 40 is placed such that it can still move above the pocket 44 when the substrate 4 is placed on the base plate 1, potentially reducing the thermal connection. It is therefore substantially parallel to the base plate 1. For this reason, there is an overhang 440 in the pocket 44, as shown in FIG. 6, which forms an upper boundary (lid) for the temperature sensor 40, preventing it from being pushed out during assembly. The temperature sensor 40 is placed in FIG. 7 such that it is always in contact with the base plate 1 during assembly, even when it pushes it upward. It is thus aligned vertically. There is also a pocket 44 for the temperature sensor 40 in this embodiment. In all of the embodiments shown in FIGS. 1 to 7, the part of the pocket 44 where the temperature sensor 40 is supposed to come in contact with the base plate 1 is not coated. A gap filler can be advantageously placed in the pocket 44 to attach the temperature sensor 40 to the base plate 1, and to reinforce it, as well as to improve the thermal contact.

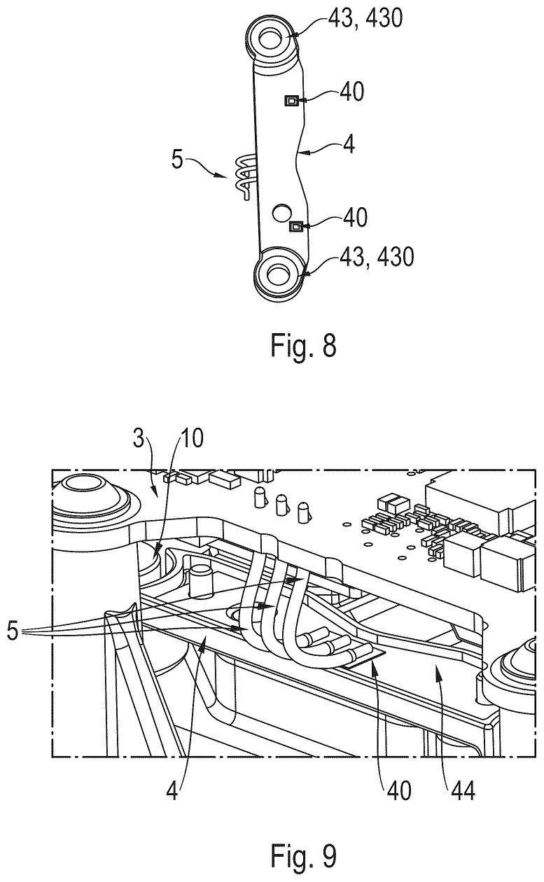

In the embodiment shown in FIGS. 8 and 9, a plate 45 is embedded in the substrate 4, on which a temperature sensor 40 is placed. The substrate 4 encompasses the plate 45 such that it does not cover the temperature sensor 40, as shown in FIG. 8 (showing the substrate 4 from below). There are contact elements 42 on the side of the printed circuit board 3 opposite the temperature sensor 40 with which the temperature sensor 40 is connected to the printed circuit board 3 above the power semiconductors 2. This can be obtained with the contact elements 42 described in reference to FIGS. 1 to 7. There can also be a socket on the printed circuit board 3 into which the line 5 (wire) can be inserted (and soldered in place), as shown in FIG. 9.

There is a point in all of the embodiments on the printed circuit board 3 above the power semiconductors 2 where contact can be made to the contact elements 42 in order to transmit the measurement values of the temperature sensor 40 to the printed circuit board 3 for processing.

The temperature sensor 40 is advantageously attached to the base plate 1 by a gap filler in all of the embodiments.

The number and position(s) of the temperature sensor(s) 40 can be determined depending on the application. FIG. 1 shows an embodiment in which the base plate 1 has three phases U, V, W. There is just one temperature measuring system (substrate 4 with components) placed on an edge (phase U), in which the substrate 4 can be attached to opposing holes 10, and which has two temperature sensors 40. These temperature sensors 40 are placed above a coolant connection, in order to measure the temperature of the coolant there through the heat exchange with the base plate 1. This embodiment can be expanded by placing a second temperature measuring system on the opposite edge (at the right in FIG. 1), and/or between the phases U, V, W.

Depending on the embodiment, there may be just one temperature sensor 40 for each base plate 1 (regardless of the number of phases U, V, W). This is placed on a coolant outlet in one embodiment, i.e. on an edge of the base plate 1. There are particular advantages to monitoring the temperature at the coolant outlet, because all of the power semiconductors 2 contribute to the heat here.

There can also be a temperature sensor 40 at a coolant inlet and at a coolant outlet. There can also be temperature sensors 40 between phases U, V, W, if the base plate 1 has numerous phases U, V, W, as shown in FIG. 1. This allows for monitoring the temperatures of the power semiconductors 2 in each phase U, V, W. With this embodiment, the substrate 4 can be tailored to the available installation space, without altering the fundamental concept.

There can also be numerous temperature sensors 40 at the cooling connection, i.e. near the coolant inlet or outlet, or in the middle of the base plate 1, with which the temperature sensor 40 can be connected directly to the base plate 1 between the individual phases U, V, W, or power semiconductors 2. This allows for redundancy.

In another embodiment, an additional functional component (not shown) is integrated in the substrate 4, i.e. embedded therein, or attached thereto. This is ideally a redundant active discharge (RAD) element. This is used to safely discharge the intermediate circuit capacitor in the inverter. The RAD element forms a resistor, which converts the electricity stored in the intermediate circuit capacitor in the inverter into heat in the event of a malfunction, to obtain a safe state. By placing it on the substrate 4, which is on the base plate 1 and therefore near the coolant, the RAD element can be heated more effectively. There is also no need to attach it to the cooling area. The RAD element and temperature sensor 40 do not affect one another, because the RAD element is only active during a malfunction, when the temperature sensor 40 is inactive (no measurements are taken).

As stated above, the temperature measuring system described herein is used for measuring the temperatures of power semiconductors 2 in an inverter used in the automotive industry. This is conventional inverter structure, for which reason only those components needed for the temperature measuring system are described. In accordance with various embodiments, there is a base plate 1 that forms both a substrate and cooling plate for a given number of power semiconductors 2, which is made of a thermally conductive material such as copper or aluminum. There are power semiconductors 2 for one or more phases U, V, W on the upper surface, with which a single or multi-phase module is formed. There are one or more cooling channels on the lower surface of the base plate 1, which are supplied with coolant through one or more coolant inlets, which is conducted to one or more coolant outlets, where it is drained. There are busbars above the power semiconductors 2. A printed circuit board 3 is placed above them (indicated in FIG. 9), with which at least signals are transmitted. This means that sensor signals (such as measurement values from the temperature sensors 40 on the substrate 4) are sent thereto and then sent through conductor paths integrated therein to a microcontroller or control unit for processing. Contact elements 42 on the sensors are in contact with the printed circuit board 3 for signal transfer. If these are spring contacts, they are tensioned when a printed circuit board 3 is placed thereon. With pins, there are holes in the printed circuit board 3 through which the pins are inserted and can be soldered in place. Other connections can be used for other contact elements 42, e.g. lands, sockets, exposed conductor paths for direct connection, etc.

A substrate 4 with at least one integrated temperature sensor 40 significantly simplifies assembly, and results in a modular structure. The number of temperature sensors 40 on the substrate 4 may vary, as well as the number and positioning of the substrates 4, because they must be adapted to the topology of the base plate 1, but can be produced as separate components. Because it is extremely easy to adapt the substrates 4, they can be placed on base plates 1 of different designs, in particular single and multi-phase modules, as long as there are other attachment points 10 for this.

An inverter with the temperature measuring system described herein is part of a power electronics module used for operating an electric drive for a vehicle that is powered at least in part with a battery or fuel cell. The vehicle is a utility vehicle in particular, e.g. a truck or bus, or a passenger automobile. The power electronics module contains a DC/AC inverter. It can also contain an AC/DC rectifier, a DC/DC converter, a transformer, and/or some other electrical converter, or it can comprise part of such a converter, or be part thereof. In particular, the power electronics module is used to provide electricity to an electric machine, e.g. an electric motor and/or generator. A DC/AC inverter is preferably used to generate a multi-phase alternating current from a direct current generated by a power source such as a battery. A DC/DC converter is used to convert (boost) a direct current from a fuel cell into a direct current that can be used by the drive.

### List of Reference Symbols

1 base plate
10 fastening point
2 power semiconductor
3 printed circuit board
4 substrate
40 temperature sensor
401 signal contact
41 lead frame
410 tabs
42 contact elements
420 ends in contact with 40
421 ends forming contacts for 3
43 screw holes
430 bushings
44 pockets
440 overhang
45 plate
5 lead
U, V, W phases

1. A temperature measuring system for a power semiconductor on an upper surface of a base plate serving as a cooling plate for an inverter, wherein coolant is conducted along a bottom of the base plate, at least underneath the power semiconductors, wherein the coolant is supplied through at least one first coolant inlet on an edge of the base plate and drained through at least one coolant outlet on the edge of the base plate, wherein the temperature measuring system comprises:
a substrate made of an electrically non-conductive material configured to be attached to the base plate;
at least one temperature sensor embedded in or attached to the substrate; and
electrical contact elements attached to or partially embedded in the substrate and that protrude above the substrate,
wherein the substrate is placed on the base plate such that each temperature sensor is placed above where the coolant is conducted and mechanically attached to the base plate such that it is in thermally conductive contact therewith.

2. The temperature measuring system according to claim 1, wherein a temperature sensor is placed near at least one coolant outlet and/or at least one coolant inlet.

3. The temperature measuring system according to claim 1, wherein:
a lead frame is embedded in the substrate, which is in electrical contact with the at least one temperature sensor, or
a plate is embedded in the substrate, which is in electrical contact with the at least one temperature sensor and faces toward the base plate.

4. The temperature measuring system according to claim 1, wherein the at least one temperature sensor is a surface-mount device (SMD) component or a through-hole component.

5. The temperature measuring system according to claim 4, wherein
the at least one temperature sensor is a through-hole component, and
the substrate has a pocket in which the at least one temperature sensor is at least partially inserted.

6. The temperature measuring system according to claim 1, wherein the contact elements are formed by spring contacts, through-hole pins, press-fit pins, flex foil, ribbon cables, or assembly aids for flexible electric leads that protrude above a top of the base plate.

7. The temperature measuring system according to claim 1, wherein a part of the base plate where the at least one temperature sensor is placed is the edge, or is between two phases of the inverter.

8. The temperature measuring system according to claim 1, wherein the substrate is attached to the base plate at at least one point.

9. The temperature measuring system according to claim 1, wherein at least one additional functional component is embedded in or placed on the substrate, the at least one additional functional component comprising at least one RAD resistor.

10. An inverter, comprising:
a base plate configured to function as a cooling plate, and populated on an upper surface thereof with power semiconductors, and comprising an area configured to conduct coolant along a bottom, at least below where the power semiconductors are located, wherein the coolant is supplied through at least one first coolant inlet on an edge of the base plate, and is drained through at least one coolant outlet on the edge of the base plate;
a printed circuit board above the power semiconductors and configured to at least conduct signals; and
the temperature measuring system according to claim 1, the substrate of which is attached to the base plate such that the at least one temperature sensor is in thermal contact with the base plate and connected to the printed circuit board for signal transmission.

11. An electric drive for a vehicle comprising:
at least one electric machine;
a transmission; and
an electronics module configured to control the electric drive,
wherein the electronics module comprises the inverter according to claim 10.
